(19) United States
(12) Patent Application Publication
(10) Pub. No.: US 2016/0029477 A1
(43) Pub. Date: Jan. 28, 2016

(54) WIRING SUBSTRATE, SEMICONDUCTOR DEVICE, PRINTED BOARD, AND METHOD FOR PRODUCING WIRING SUBSTRATE

(71) Applicant: NEC CORPORATION, Minato-ku, Tokyo (JP)

(72) Inventors: Mizuki IWANAMI, Tokyo (JP); Taras KUSHTA, Tokyo (JP)

(73) Assignee: NEC CORPORATION, Tokyo (JP)

(21) Appl. No.: 14/766,898

(22) PCT Filed: Feb. 24, 2014
(86) PCT No.: PCT/JP2014/000948

§ 371 Date: Aug. 10, 2015

(30) Foreign Application Priority Data
Feb. 27, 2013 (JP) 2013-036938

(51) Int. Cl. H05K 1/02; H05K 3/32; H05K 1/18

(52) U.S. Cl. CPC H05K 1/0216; H05K 1/18; H05K 3/32; H05K 2201/083; H05K 2203/06

(57) ABSTRACT

A wiring substrate, to be interposed when an electronic component including an integrated circuit is mounted on a printed wiring board, includes a signal wire transmitting a signal from the electronic component, and a power supply wire supplying a power voltage to the electronic component, and the power supply wire is coated directly with a magnetic thin coat, and the magnetic thin coat is not provided on the signal wire so that the magnetic thin coat is arranged to be separated from the signal wire.

### TECHNICAL FIELD

The present invention relates to a wiring substrate for mounting an electronic component including an integrated circuit, to a semiconductor device, to a printed board, and to a method for producing a wiring substrate. Particularly, the present invention relates to a wiring substrate for suppressing a conductive electromagnetic noise generated from an integrated circuit, to a semiconductor device, to a printed board, and to a method for producing a wiring substrate.

### BACKGROUND ART

In a printed board in which an electronic component including a large scale integrated circuit (LSI in the following) is mounted on a printed wiring board, a high-frequency electromagnetic noise propagates through a power supply wire or a ground wire, accompanying operation of the LSI (LSI: large scale integration). When a high-frequency electromagnetic noise flows into the printed wiring board, an unintended electromagnetic radiation noise can be generated from the printed wiring board. It can be considered that through a power-supply-or-ground-layer (power supply system) of the printed wiring board, a noise is mixed into an integrated circuit around the LSI generating a strong noise, and an electronic device can malfunction.

The NPL 1 discloses a method of suppressing and blocking an electromagnetic noise generated in a power supply system of an LSI and conducting in a printed wiring board. In the NPL 1, an electromagnetic band gap (referred to as EBG in the following) structure is formed in the printed wiring board (EBG: electromagnetic band gap).

FIG. 11 and FIG. 12 illustrate one example for describing the EBG structure of the NPL 1. The EBG structure 104 illustrated in FIG. 11 and FIG. 12 is formed as a configuration body aligned between a power supply plane 102 and a ground plane 103, and is electrically connected to the ground plane 103. In a sectional view of a printed board 100 illustrated in FIG. 12, the power supply plane 102, the ground plane 103, and the EBG structure 104 are provided inside a printed wiring board 101. The EBG structure 104 includes a via 106 connected to the ground plane 103, and a high-impedance surface 105 arranged in parallel with the power supply plane 102. An LSI package 107 mounted on the printed wiring board 101 is connected to the power supply plane 102 and the ground plane 103. In a configuration as illustrated in FIG. 11 and FIG. 12, since an electromagnetic noise conducting in the printed wiring board 101 is suppressed and blocked by the EBG structure 104, influence of the electromagnetic noise upon operation of the LSI package 107 can be reduced.

The PTL 1 discloses a technique of attaching a soft-magnetic thin coat to a lead in a semiconductor package for the purpose of attenuating a noise propagating from an LSI to a printed wiring board.

### CITATION LIST

### Patent Literature

[PTL 1] Japanese Laid-open Patent Publication No. 2011-49198

### Non Patent Literature

[NPL 1] S. Shahparnia, O. M. Ramahi, IEEE Transactions on Electromagnetic Compatibility, November 2004, Vol. 46, No. 4, pp. 580-587

### SUMMARY OF INVENTION

### Technical Problem

According to the NPL 1, when a propagating path of a noise in a printed wiring board is apparent, forming an EBG structure in the path obtains an advantageous effect that an electromagnetic noise is suppressed and blocked. However, there is a problem that when a propagating path of a noise in a printed wiring board is unknown, an advantageous effect that an electromagnetic noise is suppressed and blocked is not necessarily obtained.

When a soft-magnetic thin coat is formed on a power-supply-system lead of a semiconductor package as in the PTL 1, an electromagnetic noise can be attenuated before the propagation in a printed wiring board. For this reason, even when a propagation path of a noise in the printed wiring board is unknown, an effective measure against an electromagnetic noise can be made. However, there is a problem that when a lead through which a signal propagates neighbors a power-supply-system lead, attachment of a magnetic thin coat to a power-supply-system lead surface can affect quality of a signal.

An object of the present invention is to provide a technique of suppressing or inhibiting an electromagnetic noise leaking from a power supply system of an integrated circuit to a power supply system of a printed wiring board without affecting quality of input and output signals of the integrated circuit even when a noise propagation path in the printed wiring board is unknown.

### Solution to Problem

A wiring substrate of the present invention is a wiring substrate to be interposed when an electronic component including an integrated circuit is mounted on a printed wiring board, the wiring substrate including: a signal wire transmitting a signal from the electronic component; a power supply wire supplying a power voltage to the electronic component; and a magnetic thin coat directly coating the power supply wire; wherein the magnetic thin coat is arranged to be separated from the signal wire.

A method for producing a wiring substrate of the present invention is a method for producing a wiring substrate to be interposed when an electronic component including an integrated circuit is mounted on a printed wiring board, the method including: forming a signal wire transmitting a signal from the electronic component, and a power supply wire supplying a power voltage to the electronic component; and directly coating the power supply wire with a magnetic thin coat such that the magnetic thin coat is separated from the signal wire.

### Advantageous Effects of Invention

According to the present invention, without degrading quality of input and output signals of the integrated circuit, it is possible to suppress and inhibit an electromagnetic noise propagating from a power supply system of the integrated circuit to a power supply system of the printed wiring board, and to suppress an electromagnetic radiation noise that can be generated from the printed board.

### BRIEF DESCRIPTION OF DRAWINGS

FIG. 1A illustrates one example of wiring patterns of wires on a wiring substrate according to an exemplary embodiment of the present invention.

FIG. 1B illustrates one example of relation between wires and a magnetic thin coat on the wiring substrate according to the exemplary embodiment of the present invention.

FIG. 2 is a sectional view at A-A′ line in FIG. 1.

FIG. 3 is a sectional view illustrating one example of a printed board on which an electronic component including an integrated circuit has been mounted via an interposer substrate according to an exemplary embodiment of the present invention.

FIG. 4 is a plan view illustrating one example of a joint surface with the electronic component including the integrated circuit, in the interposer substrate according to the exemplary embodiment of the present invention.

FIG. 5 is a plan view illustrating one example of a joint surface with the printed wiring board, in the interposer substrate according to the exemplary embodiment of the present invention.

FIG. 6 is a sectional view at the B-B′ line in FIG. 6.

FIG. 7A illustrates one example of wiring patterns of wires on an interposer substrate according to a first exemplary embodiment of the present invention.

FIG. 7B illustrates one example of relation between the wires and a magnetic thin coat of the interposer substrate according to the first exemplary embodiment of the present invention.

FIG. 8A illustrates one example of wiring patterns of wires on an interposer substrate according to a second exemplary embodiment of the present invention.

FIG. 8B illustrates one example of relation between the wires and a magnetic thin coat of the interposer substrate according to the second exemplary embodiment of the present invention.

FIG. 9A illustrates one example of wiring patterns of wires of an interposer substrate according to a third exemplary embodiment of the present invention.

FIG. 9B illustrates one example of relation between the wires and a magnetic thin coat of the interposer substrate according to the third exemplary embodiment of the present invention.

FIG. 10 is graphs representing frequency dependence of transmission characteristics of magnetic thin coats in interposer substrates according to embodied examples of the present invention.

FIG. 11 illustrates an EBG structure concerning the NPL 1.

FIG. 12 is a sectional view illustrating a printed board concerning the NPL 1.

### DESCRIPTION OF EMBODIMENTS

In the following, exemplary embodiments of the present invention are described with reference to the drawings. The below-described exemplary embodiments and embodied examples include limitation technically preferable for implementing the present invention, but do not limit the scope of the invention to the following. Sizes in the drawings concerning the exemplary embodiments of the present invention differ from actual sizes, each constituent element is sometimes emphatically drawn, and a part is sometimes omitted.

Intended as a wiring substrate according to the below-described exemplary embodiments of the present invention is a wiring substrate such as an interposer substrate interposed between an electronic component such as an LSI including an integrated circuit and a printed wiring board for mounting the electronic component. In the exemplary embodiments of the present invention, a board for mounting an electronic component is called a printed wiring board, and the printed wiring board on which the electronic component has been mounted is called a printed board. In other words, in the exemplary embodiments of the present invention, the printed board has a configuration in which the printed wiring board and the electronic component are connected to each other via the wiring substrate.

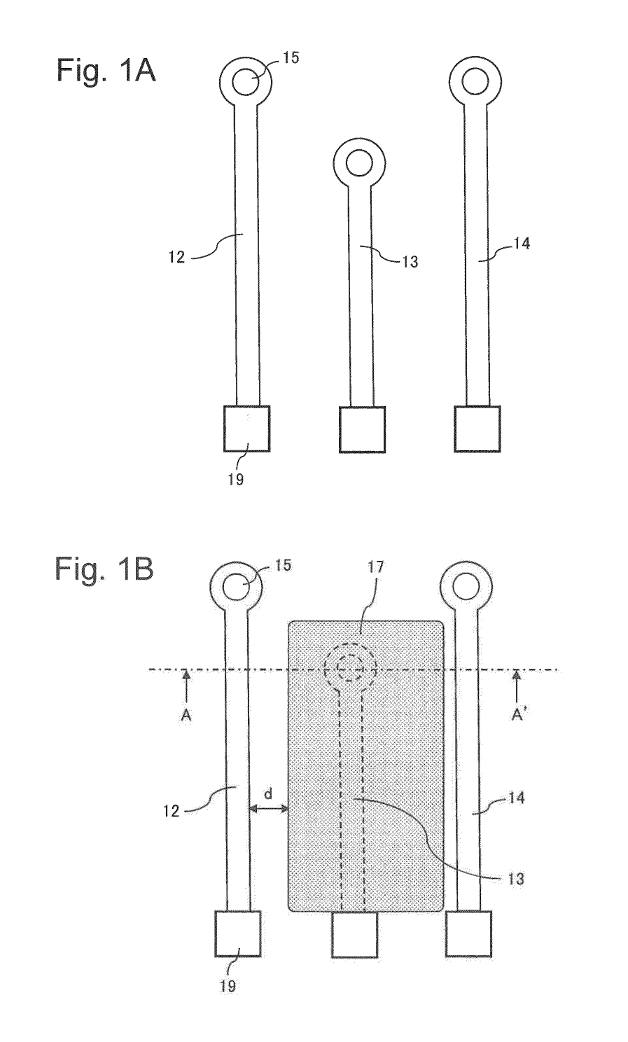

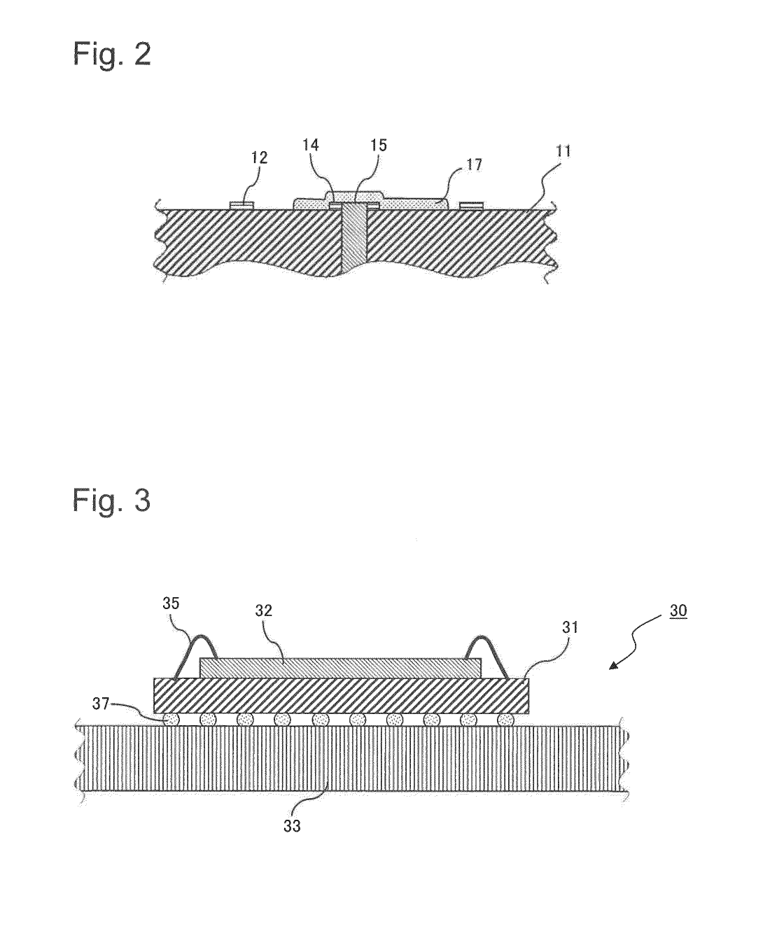

FIG. 1A and FIG. 1B illustrate one example of a wiring pattern provided on the wiring substrate 11 according to the exemplary embodiment of the present invention, and a forming location of a magnetic thin coat 17. FIG. 2 illustrates a part of a section at the A-A′ line in FIG. 1B, and schematically illustrates a configuration of a surface and an inside of the wiring substrate 11 according to the exemplary embodiment of the present invention.

In FIG. 1A and FIG. 1B, the wiring substrate 11 illustrated in FIG. 2 is omitted. FIG. 1A, FIG. 1B, and FIG. 2 illustrate an example where the wiring pattern is formed on the surface of the wiring substrate 11, and the surface of the wiring substrate 11 may be coated with an insulating coat after the magnetic thin coat 17 is formed, and a configuration of the exemplary embodiment of the present invention may be provided inside the wiring substrate.

FIG. 1A illustrates one example of the wiring pattern before the magnetic thin coat 17 is formed. The wiring pattern in FIG. 1 is one example, and a shape and arrangement of the wiring pattern can be variously changed.

The wiring pattern includes a signal wire 12 that propagates a signal between electronic components such as LSIs including integrated circuits mounted on the printed wiring board, a power supply wire 13 for supplying electric power to the integrated circuits, and a ground wire 14 that connects the integrated circuits to a ground. The wiring pattern in FIG. 1A is a drawing that simplifies the wiring substrate 11 of the exemplary embodiment of the present invention, and actually, the wiring substrate on which a plurality of wiring patterns are formed is intended. In the present exemplary embodiment, the power supply wire 13 and the ground wire 14 are written so as to be distinguished from each other, and however, the ground wire 14 is one of the power supply wires.

Each wire illustrated in FIG. 1A is electrically connected to a wire on an opposite-side surface of the wiring substrate through a via 15, or to an inside wiring layer. Each wire of FIG. 1A is electrically connected to the printed wiring board, the electronic component, or the like through a bonding pad 19. The bonding pads 19 are provided to all wiring patterns illustrated in FIG. 1A and FIG. 1B.

FIG. 1B illustrates relation between the wiring pattern and the magnetic thin coat 17 when the magnetic thin coat 17 is formed on the power supply wire 13. In FIG. 1B, a shape of the power supply wire 13 is drawn by the broken line within a region where the magnetic thin coat 17 is formed, and however, the power supply wire 13 is coated directly with the magnetic thin coat 17 and is not exposed. In the present exemplary embodiment, an example of coating the power supply wire 13 with the magnetic thin coat 17 is illustrated, and however, the same applies to a case where not the power supply wire 13 but the ground wire 14 is coated with magnetic thin coat 17. Both the power supply wire 13 and the ground wire 14 may be coated with the magnetic thin coat 17.

In the exemplary embodiment of the present invention, the magnetic thin coat 17 coats the power supply wire 13. As illustrated in FIG. 2, the magnetic thin coat 17 is formed directly on the power supply wire 13 so as to coat the power supply wire 13. The magnetic thin coat 17 coats the power supply wire 13 including not only an upper part of the power supply wire 13 but also a side part of the power supply wire 13.

To suppress a propagating electromagnetic noise as much as possible, it is preferable that an entire surface of the wiring pattern formed as the power supply wire 13 or the ground wire 14 is coated with the magnetic thin coat 17. If an advantageous effect of suppressing a propagating electromagnetic noise is obtained, the bonding pad 19 may be regarded as the wiring pattern, and may be coated with the magnetic thin coat 17.

The magnetic thin coat 17 and the signal wire 12 are arranged at an interval equal to or larger than a specific distance. A distance d between the magnetic thin coat 17 and the signal wire 12 is preferably equal to or larger than a half of a width of the signal wire 12. The distance d between the magnetic thin coat 17 and the signal wire 12 is preferably a fixed distance.

The distance between the magnetic thin coat 17 and the signal wire 12 is not related to the distance between the wire coated with the magnetic thin coat 17 and the signal wire 12, and is considered by a distance between the magnetic thin coat 17 and the signal wire 12. In other words, at a location where a distance between the signal wire 12 and the magnetic thin coat 17 is defined, a peripheral part of the magnetic thin coat 17 is formed along an external shape of the signal wire 12. However, at a location where the distance between the signal wire 12 and the magnetic thin coat 17 is not constant, it is sufficient that the interval equal to or larger than the fixed distance exists. For this reason, the peripheral part of the magnetic thin coat 17 is not necessarily formed along the external shape of the signal wire 12.

FIG. 1B is drawn such that only the power supply wire 13 is coated with the magnetic thin coat 17, and however, in addition to the power supply wire 13, at least a part of the ground wire 14 separated from the signal wire 12 may be coated. Further, when the ground wire 14 is closer to the signal wire 12 than the power supply wire 13 is, it is desirable to coat the ground wire 14 with the magnetic thin coat 17. Furthermore, while the signal wire 12 is not coated with the magnetic thin coat 17, all of the other power supply wire 13 and the ground wire 14 may be coated with the magnetic thin coat 12.

In FIG. 1B, the respective wirings are illustrated only one by one for minimizing the wiring pattern. However, in a general case such as a case where the power supply wire 12 or the ground wire 13 is arranged on the both sides of the signal wire 12 e.g., a plurality of wiring patterns are provided. In such a case, preferably, all of the power supply wires 13 or the ground wires 14 arranged so as to neighbor the signal wire 12 are coated with the magnetic thin coats 17. When arrangement of the wires is not made in a regular manner such as that in FIG. 1A, it is desirable to set, as the positional relation described in the present exemplary embodiment, an interval between the signal wire 12 and the magnetic thin coat 17 that is provided so as to coat the power supply wire 13 or the ground wire 14 close to the signal wire 12. It is preferable to consider, as the power supply wire 13 or the ground wire 14 close to the signal wire 12, not only the closest wire but also all the wires at positions affected by an electromagnetic noise.

Further, the relation between the wires and the magnetic thin coat according to the exemplary embodiment of the present invention can apply not only to wires on a two-dimensional plane surface, but also to wires on a curved surface such as a spherical surface. The relation between the wires and the magnetic thin coat according to the exemplary embodiment of the present invention can apply not only to wires on the surface of the wiring substrate, but also to wiring layers inside the wiring substrate.

As the magnetic thin coat 17, a thin coat including a ferritic material can be used. For example, as the ferritic material, spinel ferrite, hexagonal ferrite, garnet ferrite, or the like can be used, and particularly, spinel ferrite is suitable. As an example of the spinel ferrite, magnetite, manganese-zinc ferrite, nickel-zinc ferrite, copper-zinc ferrite, or the like can be cited. The magnetic thin coat 17 is not limited to the ferritic material, and may be a magnetic material, such as a cobalt-iron-boron material or an iron-boron material, suitable for shielding an electromagnetic noise generated at a high-frequency region.

A thickness of the magnetic thin coat 17 is not particularly limited, and however, when it is equal to or smaller than approximately 10 μm, a property different from that of a bulk material can be obtained. For this reason, when the magnetic thin coat 17 is made mainly of a single material, it is preferably equal to or smaller than 10 μm.

The magnetic thin coat 17 can be formed as a thin coat by a plating method, a printing method, an aerosol deposition method, a vapor deposition method, a sputtering method, or the like. Particularly, as a method for forming the magnetic thin coat 17 on the wiring substrate 11, a plating method or a printing method is suitable.

For example, according to a plating method, the wiring substrate 11 including a plating-target location where a hydroxyl group has been adsorbed is soaked in an aqueous solution including iron ions, and the iron ions are then oxidized by an oxidizing agent so that a ferrite thin coat having a desired shape can be formed. Further, for example, according to a printing method, a paste made from a resin including dispersed magnetic material fine particles is screen-printed on the substrate, and a solvent is dried so that a magnetic thin coat having a desired shape can be formed.

The above is the description for the configuration of the wiring substrate according to the exemplary embodiment of the present invention.

Next, as one example of the wiring substrate 11 illustrated in FIG. 1A, FIG. 1B, and FIG. 2, an interposer substrate 31 is cited and described.

In a printed board 30 of FIG. 3, the interposer substrate 31 is mounted on a printed wiring board 33 via solder balls 37, and on the interposer substrate 31, an LSI chip 32 is mounted. The printed wiring board 33 and the LSI chip 32 are electrically connected to each other with the interposer substrate 31 interposed therebetween. Concretely, the LSI chip 32 and the interposer substrate 31 are connected to each other by bonding wires 35, and the printed wiring board 33 and the interposer substrate 31 are connected to each other by the solder balls 37. The LSI chip 32 according to the exemplary embodiment of the present invention may be an electronic component including an electronic circuit such as an integrated circuit.

As illustrated in FIG. 3, the general interposer substrate 31 is arranged so as to be interposed, as a structure body for mounting the LSI chip 32 on the printed wiring board 33, between the LSI chip 32 and the printed wiring board 33. Accordingly, even when a wire pitch differs between the printed wiring board 33 and the LSI chip 32, the connection can be made via the interposer 31.

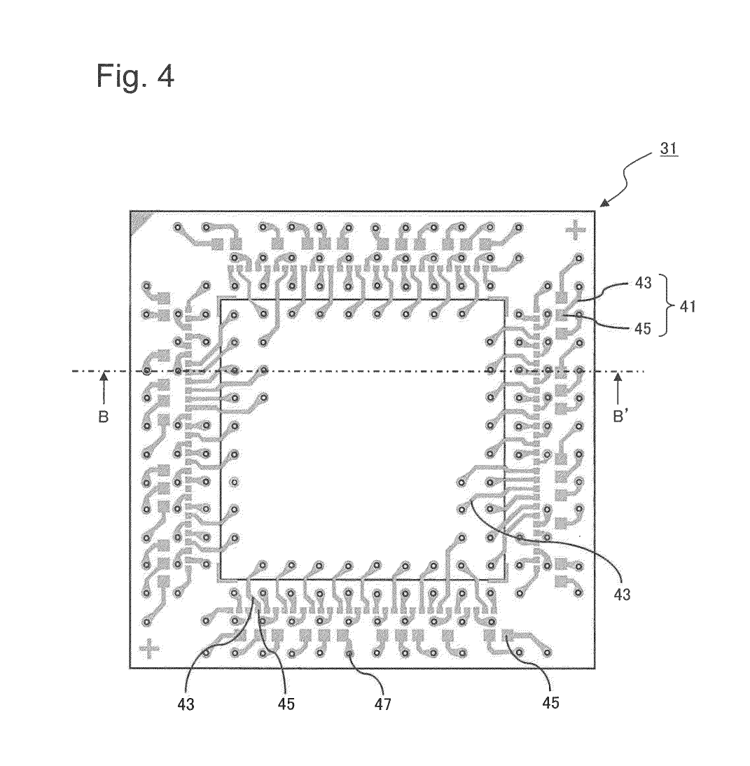

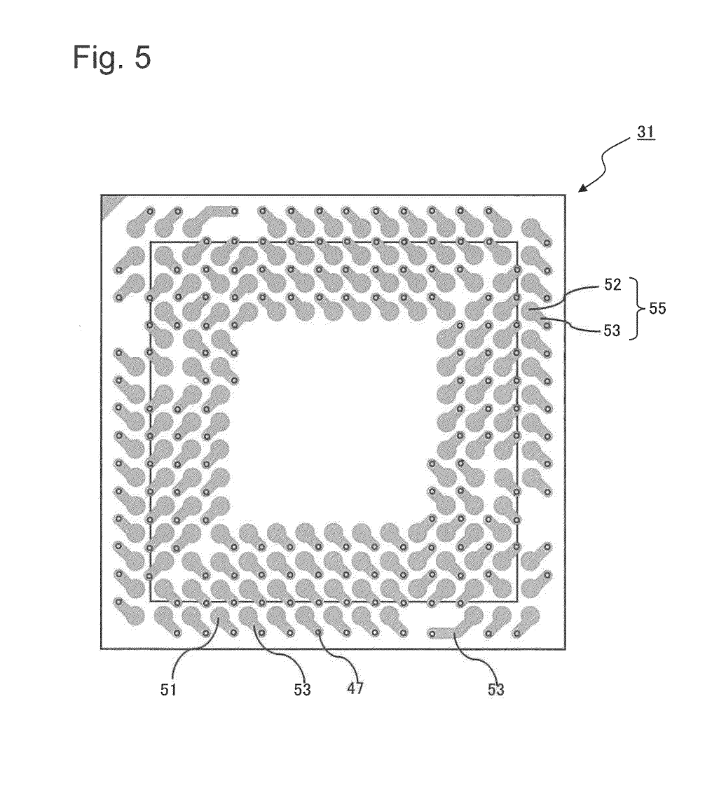

FIG. 4 to FIG. 6 illustrate one example of the interposer substrate 31. While wiring patterns in FIG. 4 and FIG. 5 have various shapes, any one of them is used as the signal wire 12, the power supply wire 13, or the ground wire 14. In FIG. 4 and FIG. 5, marks irrelevant to the essence of the present invention and used at the time of mounting, and the like are drawn. For example, it is possible to use, as the interposer substrate 31 illustrated in FIG. 4 to FIG. 6, a wiring substrate having a plane size of the 8.2 mm square and having a double-layer structure.

The interposer substrate 31 includes a surface (FIG. 4) on the side of which the LSI chip 32 is mounted, and a surface (FIG. 5) of which side is mounted on the printed wiring board 33. On surface (FIG. 4) on the side of which the LSI chip 32 is mounted, an LSI-side pattern 41 including an LSI-side wire 43 and a bonding pad 45 is provided. On the surface (FIG. 5) of which side is mounted on the printed wiring board 33, a printed-wiring-board-side pattern 51 including a printed-wiring-board-side wire 53 and a solder-ball pad 55 is provided. Further, on the interposer substrate 31, a via 47 for electrically connecting the LSI-side pattern 41 and the printed-wiring-board-side pattern 51 to each other is provided.

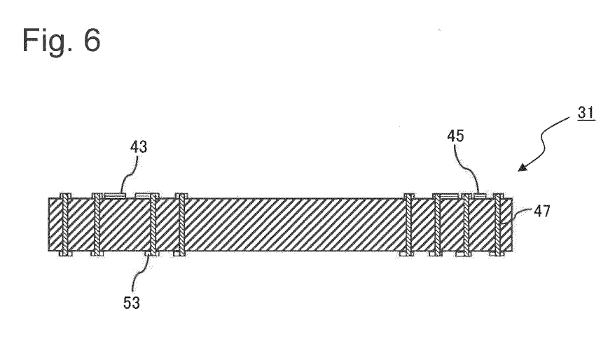

As illustrated in FIG. 6, a sectional view at the B-B′ line of FIG. 4, the via 47 penetrating an inside of the interposer substrate 31 electrically connect the LSI-side pattern 41 and the printed-wiring-board-side pattern 51 to each other. FIG. 6 illustrates an example in which one via 47 penetrates the interposer substrate 31, and however, multi-layered wirings constituted by a plurality of wiring layers may be provided inside the interposer substrate 31, and a plurality of vias may be provided so as to connect the wiring layers to each other.

The above is the description about the configuration of the printed board in which the electronic component including the integrated circuit is mounted on the printed wiring board while the wiring substrate according to the exemplary embodiment of the present invention is interposed as the interposer substrate therebetween.

In the wiring substrate (interposer substrate) according to the exemplary embodiment of the present invention, the magnetic thin coat that coats at least one of the power supply wire and the ground wire is formed such that an interval between the magnetic thin coat and the signal wire is equal to or larger than a fixed distance. Preferably, the magnetic thin coat is formed such that an interval between the magnetic thin coat and the signal wire is a fixed distance. In the exemplary embodiment of the present invention, between the LSI chip including an integrated circuit and the printed wiring board, the above-described wiring substrate is interposed. Thereby, without affecting signal quality, it is possible to suppress a noise conducting from the LSI chip to the printed wiring board through a power supply or a ground.

The magnetic thin coat provided in the above-described wiring substrate reflects or absorbs a noise propagating through the power supply wire or the ground wire. Further, keeping an interval between the signal wire and the magnetic thin coat constant can prevent signal reflection accompanying signal attenuation or discontinuity of characteristic impedance in a wiring.

In other words, according to the wiring substrate of the exemplary embodiment of the present invention, without affecting signal quality of the integrated circuit, a noise can be suppressed from leaking to the printed wiring board from the integrated circuit. For this reason, a noise caused by the integrated circuit can be suppressed from propagating to the printed wiring board, and an electromagnetic radiation noise that can be generated from the printed board can be suppressed.

The scope of the present invention includes a semiconductor device in which the electronic component including the integrated circuit is mounted on the wiring substrate according to the exemplary embodiment of the present invention. Further, the scope of the present invention also includes a printed board in which the electronic component including the integrated circuit is mounted on the printed wiring board via the wiring substrate according to the exemplary embodiment of the present invention. Furthermore, the scope of the present invention includes an electromagnetic noise propagation suppressing method of interposing, between the electronic component and the printed wiring board, the wiring substrate in which a wiring including the power supply wire and the ground wire is coated with the magnetic thin coat, and the magnetic thin coat and the signal wire are arranged at an interval.

As described above, according to the exemplary embodiment of the present invention, without degrading quality of input and output signals in an electronic component such as an LSI including an integrated circuit, it is possible to suppress a noise propagating from the power supply system of the integrated circuit to the printed-wiring-board power supply system. As a result, an electromagnetic radiation noise that can be generated from the printed board can be suppressed.

Next, the exemplary embodiment of the present invention is described by citing a concrete configuration example and using drawings.

### First Exemplary Embodiment

In the interposer substrate 31 according to the first exemplary embodiment, the magnetic thin coat 17 is provided so as to coat the power supply wire 13.

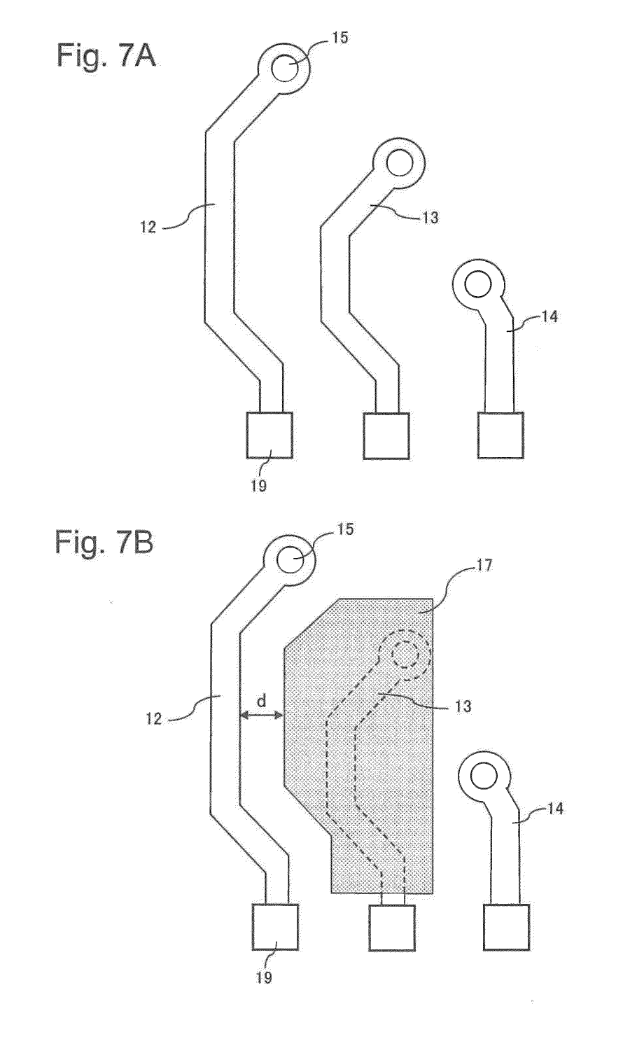

FIG. 7A illustrates arrangement of a wiring on the interposer substrate 31, the wiring including the signal wire 12, the power supply wire 13, and the ground wire 14. Each wire includes the bonding pad 19, and is connected through the via 15 to a wiring layer inside the interposer substrate 31 or a wiring layer at the opposite surface. FIG. 7A illustrates only a selected part on the interposer substrate 31, and on the interposer substrate 31, a plurality of wires as illustrated in FIG. 4 for example are formed.

On the interposer substrate 31 that is an example of the wiring substrate according to the first exemplary embodiment of the present invention, the magnetic thin coat 17 as illustrated in FIG. 7B is selectively formed so as to coat the power supply wire 13. In FIG. 7B, a shape of the power supply wire 13 is depicted by the broken line inside a region where the magnetic thin coat 17 is formed, and however, the power supply wire 13 is coated directly with the magnetic thin coat 17 and is not exposed. In the interposer substrate 31 according to the first exemplary embodiment, on the ground wire 14, the magnetic thin coat 17 is not provided.

The magnetic thin coat 17 is arranged to be in direct contact with the power supply wire 13. The magnetic thin coat 17 is arranged so as to coat not only the upper portion of the power supply wire 13 but also an exposed portion such as a side portion of the power supply wire 13.

A peripheral portion of the magnetic thin coat 17 on the side closer to the signal wire 12 is not in contact with the signal wire 12, and the magnetic thin coat 17 and the signal wire 12 are arranged at an interval. A distance d between the signal wire 12 and the magnetic thin coat 17 is desirably equal to or larger than a half of a width of the signal wire 12. By such formation of the magnetic thin coat 17, the magnetic thin coat 17 does not affect signal quality.

Particularly, the distance d between the signal wire 12 and the magnetic thin coat 17 is preferably kept constant. When the magnetic thin coat 17 does not exist on the signal wire 12 and the distance between the signal wire 12 and the magnetic thin coat 17 is kept constant, it is possible to prevent attenuation of a signal, and reflection of a signal accompanying discontinuity of characteristic impedance in the wiring.

The magnetic thin coat 17 is formed by a plating method, using a mask for obtaining a desired pattern shape, for example. A method for forming the magnetic thin coat is not limited to a plating method, and a pasted magnetic material made by mixing magnetic powder and a resin e.g., may be screen-printed to form the thin coat, or the thin coat may be formed by an aerosol deposition method, a vapor deposition method, a sputtering method, or the like.

A conduction noise generated in the power supply wire 13 of the LSI chip 32 is reflected or absorbed by the magnetic thin coat 17 on the power supply wire 13 of the interposer substrate 31. For this reason, in the LSI chip 32 and the printed wiring board 33 connected to each other via the interposer substrate 31, a noise leaking from the LSI chip 32 to the printed wiring board 33 can be suppressed.

In the first exemplary embodiment of the present invention, the interposer substrate provided with a measure for, without affecting signal quality, suppressing a noise conducting through the power supply is interposed between the LSI chip and the printed wiring board. Concretely, the magnetic thin coat is formed so as to coat the power supply wire of the interposer substrate. Further, it is possible to interpose the interposer substrate in which an interval between the magnetic thin coat and the signal wire is kept constant.

The above-described interposer substrate enables a noise conducting through the power supply wire to be reflected or absorbed by the magnetic thin coat. Further, keeping an interval between the signal wire and the magnetic thin coat constant can prevent attenuation of a signal, and reflection of a signal accompanying discontinuity of characteristic impedance in the wiring.

Therefore, according to the interposer substrate of the first exemplary embodiment of the present invention, noise leakage from the integrated circuit to the printed wiring board can be suppressed without affecting signal quality of the integrated circuit.

### Second Exemplary Embodiment

In the interposer substrate 31 according to the second exemplary embodiment, the magnetic thin coat 17 is provided so as to coat the ground wire 14, which differs from the first exemplary embodiment.

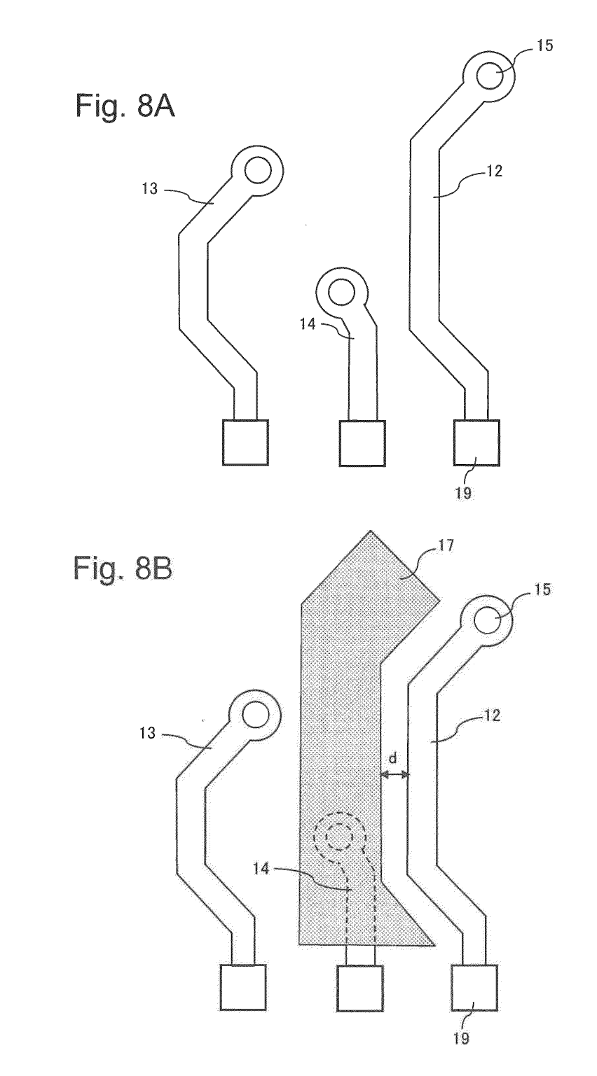

FIG. 8A illustrates arrangement of a wiring on the interposer substrate 31, the wiring including the signal wire 12, the power supply wire 13, and the ground wire 14. In FIG. 8A, only a part of the wiring on the interposer substrate 31 is selected and illustrated in the same manner as the wiring illustrated in FIG. 7A.

In the interposer substrate 31 that is an example of the wiring substrate according to the second exemplary embodiment of the present invention, the magnetic thin coat 17 as illustrated in FIG. 8B is selectively formed so as to coat the ground wire 14. In FIG. 8B, a shape of the ground wire 14 is depicted by the broken line within a region where the magnetic thin coat 17 is formed, and however, the ground wire 14 is coated directly with the magnetic thin coat 17 and is not exposed. In the interposer substrate 31 according to the second exemplary embodiment, the magnetic thin coat 17 is not provided on the power supply wire 13.

The magnetic thin coat 17 is arranged to be in direct contact with the ground wire 14. The magnetic thin coat 17 is arranged so as to coat not only a surface of the ground wire 14 but also an exposed portion such as a side portion of the ground wire 14.

In the same manner as in the first exemplary embodiment, the peripheral portion of the magnetic thin coat 17 on a side closer to the signal wire 12 is not in contact with the signal wire 12, and the magnetic thin coat 17 and the signal wire 12 are arranged at an interval. A distance d between the signal wire 12 and the magnetic thin coat 17 is desirably equal to or larger than a half of a width of the signal wire 12. According to such formation of the magnetic thin coat 17, the magnetic thin coat 17 does not affect signal quality.

In addition, the distance d between the signal wire 12 and the magnetic thin coat 17 is preferably kept constant. When the magnetic thin coat 17 does not exist on the signal wire 12 and the distance between the signal wire 12 and the magnetic thin coat 17 is kept constant, it is possible to prevent attenuation of a signal, and reflection of a signal accompanying discontinuity of characteristic impedance in the wiring.

In the same manner as in the first exemplary embodiment, the magnetic thin coat 17 can be formed by a plating method or a printing method, using a mask for obtaining a desired pattern shape.

A conduction noise generated in the ground wire 14 of the LSI chip 32 is reflected or absorbed by the magnetic thin coat 17 on the ground wire 14 of the interposer substrate 31. For this reason, in the same manner as in the first exemplary embodiment, in the LSI chip 32 and the printed wiring board 33 connected to each other via the interposer substrate 31, a noise leaking from the LSI chip 32 to the printed wiring board 33 can be suppressed.

In the second exemplary embodiment of the present invention, in the same manner as in the first exemplary embodiment, the interposer substrate provided with a measure for, without affecting signal quality, suppressing a noise conducting through the ground is interposed between the LSI chip and the printed wiring board.

The above-described interposer substrate enables a noise conducting through the ground wire to be reflected or absorbed by the magnetic thin coat. Further, keeping a distance between the signal wire and the magnetic thin coat constant can prevent attenuation of a signal, and reflection of a signal accompanying discontinuity of characteristic impedance in the wiring.

Therefore, also by the interposer substrate of the second exemplary embodiment of the present invention, in the same manner as in the first exemplary embodiment, noise leakage from the integrated circuit to the printed wiring board can be suppressed without affecting signal quality of the integrated circuit.

### Third Exemplary Embodiment

In the interposer substrate 31 according to the third exemplary embodiment, the magnetic thin coat 17 is provided so as to coat the power supply wire 13 and the ground wire 14.

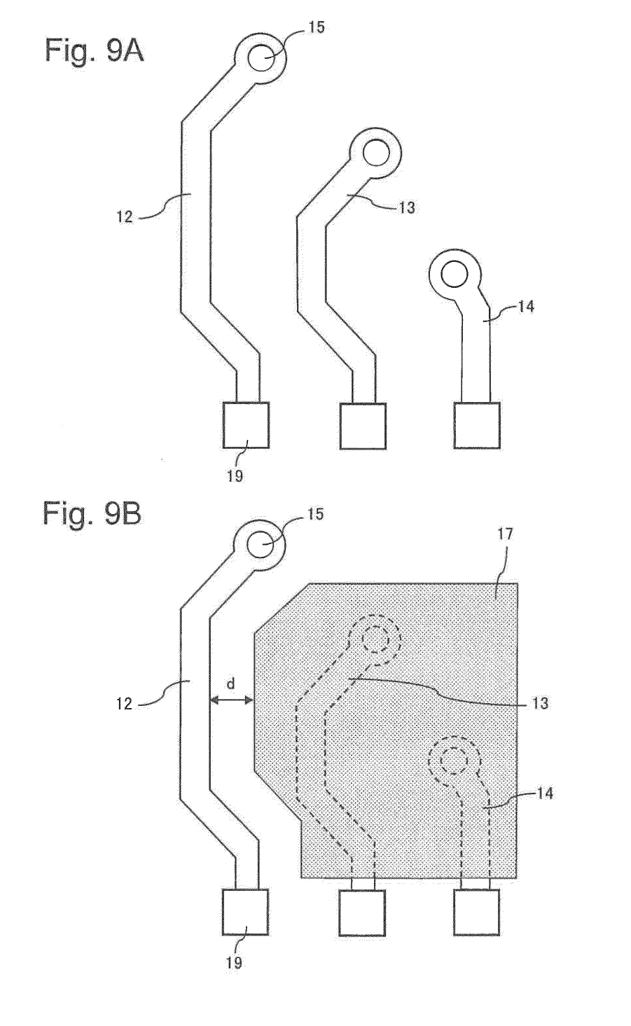

FIG. 9A illustrates arrangement of a wiring on the interposer substrate 31, the wiring including the signal wire 12, the power supply wire 13, and the ground wire 14. In FIG. 9A, only a part of the wiring on the interposer substrate 31 is selected and illustrated in the same manner as the wiring illustrated in FIG. 7A.

In the interposer substrate 31 that is an example of the wiring substrate according to the third exemplary embodiment of the present invention, the magnetic thin coat 17 as illustrated in FIG. 9B is selectively formed so as to coat the power supply wire 13 and the ground wire 14. In FIG. 9B, shapes of the power supply wire 13 and the ground wire 14 are depicted by the broken line within a region where the magnetic thin coat 17 is formed, and however, the power supply wire 13 and the ground wire 14 are coated directly with the magnetic thin coat 17 and are not exposed. In the interposer substrate 31 according to the third exemplary embodiment, the magnetic thin coat 17 is provided so as to coat the power supply wire 13 and the ground wire 14, and however, it is unnecessary to coat the entirety of the power supply wire 13 and the ground wire 14. Nevertheless, for strengthening an advantageous effect of suppressing an electromagnetic noise, it is desirable to coat the entirety of the power supply wire 13 and the ground wire 14.

The magnetic thin coat 17 is arranged to be in direct contact with the power supply wire 13 and the ground wire 14. The magnetic thin coat 17 is arranged so as to coat not only upper sides of the power supply wire 13 and the ground wire 14 but also exposed portions such as side portions of the power supply wire 13 and the ground wire 14.

In the same manner as in the first exemplary embodiment, the peripheral portion of the magnetic thin coat 17 on a side closer to the signal wire 12 is not in contact with the signal wire 12, and the magnetic thin coat 17 and the signal wire 12 are arranged at an interval. A distance d between the signal wire 12 and the magnetic thin coat 17 is desirably equal to or larger than a half of a width of the signal wire 12. According to such formation of the magnetic thin coat 17, the magnetic thin coat 17 does not affect signal quality.

Particularly, the distance d between the signal wire 12 and the magnetic thin coat 17 is preferably kept constant. When the magnetic thin coat 17 does not exist on the signal wire 12 and the distance between the signal wire 12 and the magnetic thin coat 17 is kept constant, it is possible to prevent attenuation of a signal, and reflection of a signal accompanying discontinuity of characteristic impedance in the wiring.

In the same manner as in the first exemplary embodiment, the magnetic thin coat can be formed by a plating method or a printing method, using a mask for obtaining a desired pattern shape.

A conduction noise generated in the power supply wire 13 and the ground wire 14 of the LSI chip 32 is reflected or absorbed by the magnetic thin coat 17 on the power supply wire 13 and the ground wire 14 of the interposer substrate 31. For this reason, in the same manner as in the first exemplary embodiment, in the LSI chip 32 and the printed wiring board 33 connected to each other via the interposer substrate 31, a noise leaking from the LSI chip 32 to the printed wiring board 33 can be suppressed.

In the third exemplary embodiment of the present invention, in the same manner as in the first and second exemplary embodiments, the interposer substrate provided with a measure for, without affecting signal quality, suppressing a noise conducting through the ground is interposed between the LSI chip and the printed wiring board. The above-described interposer substrate enables a noise conducting through the ground wire to be reflected or absorbed by the magnetic thin coat. Further, keeping a distance between the signal wire and the magnetic thin coat constant can prevent attenuation of a signal, and reflection of a signal accompanying discontinuity of characteristic impedance in the wiring.

Therefore, also by the interposer substrate according to the third exemplary embodiment of the present invention, in the same manner as in the first and second exemplary embodiments, noise leakage from the integrated circuit to the printed wiring board can be suppressed without affecting signal quality of the integrated circuit.

Next, embodied examples of the exemplary embodiment of the present invention are described with reference to the drawings. For the embodied examples of the present invention, two embodied examples (embodied example 1 and embodied example 2) as examples of the interposer substrate according to the third exemplary embodiment, and one comparison example are cited, and a difference in a transmittance characteristic of the power-supply-or-ground-wire in the interposer substrate is described.

### Embodied Example 1

The embodied example 1 represents an example in which on the power supply wire 13 and the ground wire 14, a ferrite coat having a thickness of 3 μm is formed as the magnetic thin coat 17 by a plating method as illustrated in FIG. 9B.

First, a resist material that becomes a mask was applied on a region where the ferrite coat is not formed, such that the ferrite coat comes to have a shape of the magnetic thin coat 17 illustrated in FIG. 9B. Then, a hydroxyl group was adsorbed to the surface of the interposer substrate 31, the interposer substrate 31 was soaked in an aqueous solution containing iron ions, and the iron ions were oxidized by an oxidizing agent so that the ferrite thin coat was formed on the surface of the interposer substrate 31. After the ferrite coat was formed, the resist material was removed by acetone, and the ferrite coat that is the magnetic thin coat having a desired shape as in FIG. 9B was obtained.

The LSI chip 32 was mounted on the interposer substrate 31 on which the ferrite coat was formed, and the interposer substrate 31 and the LSI chip 32 are electrically connected to each other by the bonding wires 35. The interposer substrate 31 on which the LSI chip 32 was mounted was mounted on the printed wiring board 33 by the solder balls 37. The power supply wire 13 and the ground wire 14 of the interposer substrate 31 are electrically connected to a power supply system of a digital circuit block of the LSI chip 32 and to a power supply system of the printed wiring board 33. The thus-formed printed wiring board 33 on which the LSI chip 32 has been mounted comes to have the configuration as illustrated in FIG. 3.

Since a width of the signal wire 12 is 60 μm, an interval between the signal wire 12 and the ferrite coat 17 is preferably equal to or larger than 30 μm to be equal to or larger than a half of the width of the signal wire 12. For this reason, in the embodied example 1, the shortest distance d between the signal wire 12 and the magnetic thin coat 17 was set as 50 μm. In addition, to prevent signal attenuation, and signal reflection accompanying discontinuity of characteristic impedance in the wiring, the interval between the signal wire 12 and the magnetic thin coat 17 was fixed at 50 μm.

### Embodied Example 2

The embodied example 2 represents an example in which a resin magnetic composite coat having a thickness of 30 μm was formed as the magnetic thin coat 17 on the power supply wire 13 and the ground wire 14 by a screen printing method as illustrated in FIG. 9B.

First, as a printing material for forming the resin magnetic composite coat, a cobalt-iron-boron-system fine particle material and epoxy resin are mixed and agitated, and a pasted magnetic material containing 80 wt % of the magnetic fine particles was prepared. Next, by using a screen that covered a portion where the magnetic thin coat 17 is not formed, the pasted magnetic material was printed on the interposer substrate so as to form a pattern of the magnetic thin coat 17 as in FIG. 9B. After the pattern was formed, a solvent contained in the pasted magnetic material was vaporized, the resin was solidified, and the resin magnetic composite coat having a thickness of 30 μm was formed.

In the same manner as in the embodied example 1, the LSI chip 32 was mounted on the printed wiring board 33 via the interposer substrate on which the resin magnetic composite coat was formed as described above. In the same manner as in the embodied example 1, the power supply wire 13 and the ground wire 14 of the interposer substrate 31 are electrically connected to a power supply system of a digital circuit block of the LSI chip 32 and to a power supply system of the printed wiring board 33. The thus-formed printed board 30 in which the LSI chip 32 has been mounted on the printed wiring board 33 comes to have the configuration as illustrated in FIG. 3.

In the same manner as in the embodied example 1, in the embodied example 2, the shortest distance d between the signal wire 12 and the magnetic thin coat 17 was set as 50 μm. In addition, to prevent signal attenuation, and signal reflection accompanying discontinuity of characteristic impedance in the wiring, the interval between the signal wire 12 and the magnetic thin coat 17 was fixed at 50 μm.

### Comparison Example

The comparison example is a case where the magnetic thin coat 17 is not formed on the power supply wire 13 and the ground wire 14 as illustrated in FIG. 9A. The comparison example represents a case of no measure for suppressing a conduction noise, since the magnetic thin coat 17 is not provided on the power supply wire 13 and the ground wire 14.

In the same manner as in the embodied example 1, the LSI chip 32 and the printed wiring board 33 are connected to each other via an interposer substrate of the comparison example. In the same manner as in the embodied example 1, the power supply wire 13 and the ground wire 14 of the interposer substrate 31 are electrically connected to a power supply system of a digital circuit block of the LSI chip 32 and to a power supply system of the printed wiring board 33. The thus-formed printed board 30 in which the LSI chip 32 has been mounted on the printed wiring board 33 comes to have the configuration as illustrated in FIG. 3.

(Experiment Result)

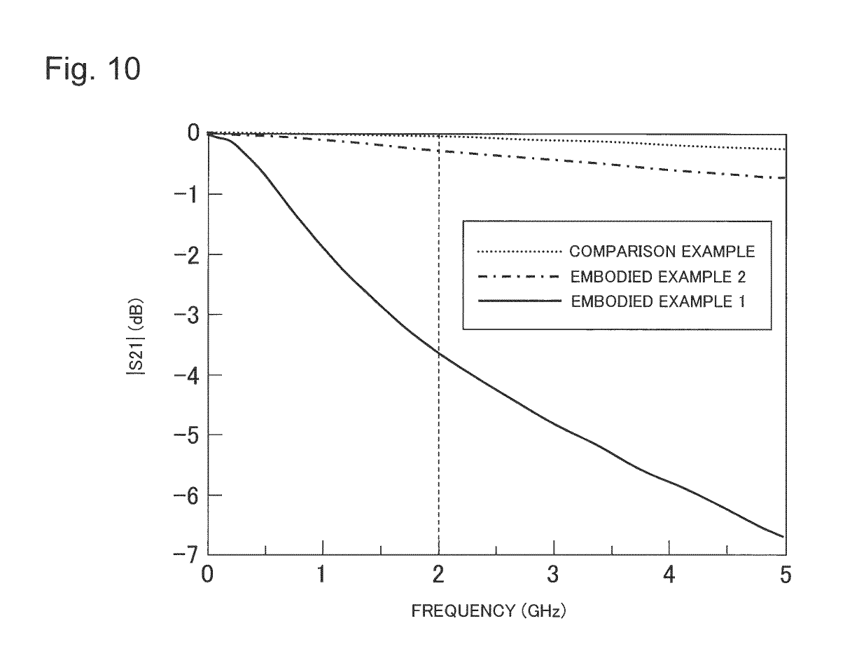

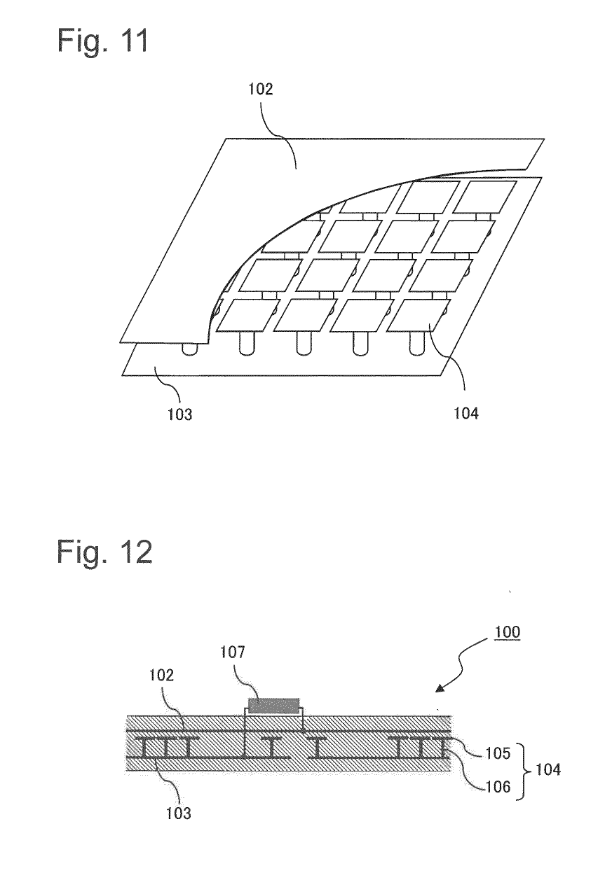

FIG. 10 illustrates transmission characteristics between the power supply wires and the ground wires in the surfaces of the interposer substrates of the embodied examples 1 and 2 and the comparison example.

For the transmission characteristics of FIG. 10, the bonding pad 45 on the surface (FIG. 4) of the interposer substrate was set as an input port, and the solder ball pad 55 on the back surface (FIG. 5) was set as an output port.

In the transmission characteristic of the comparison example (dotted line), insertion loss at 2 GHz is less than 0.05 dB. In other words, in the comparison example, a conduction noise conducts from the input port to the output port almost without attenuation.

In contrast, in the transmission characteristic of the embodied example 1 (solid line), insertion loss at 2 GHz is about 3.6 dB. In the transmission characteristic of the embodied example 2 (alternate long and short dash line), insertion loss at 2 GHz is about 0.3 dB.

This result indicates that existence of the ferrite thin coat as in the embodied example 1 suppressed a conduction noise to the power-supply-or-ground-wire in the interposer substrate. In other words, it is indicated that when the configuration of FIG. 3 is adopted, the interposer substrate 31 suppresses leakage of a conduction noise from the power-supply-or-ground-wire of the LSI chip 32 to the printed wiring board 33. Further, it can be confirmed that the resin magnetic composite coat of the embodied example 2 does not match the ferrite thin coat of the embodied example 1, and however exhibits an advantageous effect of suppressing leakage of a conduction noise as well.

In the above, the invention of the present application is described with reference to the exemplary embodiments and the embodied examples, but the invention of the present application is not limited to the above-described exemplary embodiments and embodied examples. Various alterations that a person skilled in the art can understand within the scope of the invention of the present application can be made for a configuration and details of the invention of the present application.

Applying the wiring substrate of the present invention as the interposer substrate can suppress a noise propagating from the power supply system of the LSI to the printed-wiring-board power supply system, without degrading quality of input and output signals in the LSI. As a result, it is possible to provide an electronic device such as a wireless device in which a noise measure has been effectively implemented without degrading communication quality.

The present application claims priority based on Japanese patent application No. 2013-036938 filed on Feb. 27, 2013, entire disclosure of which is incorporated herein.

### REFERENCE SIGNS LIST

11 wiring substrate
12 signal wire
13 power supply wire
14 ground wire
17 magnetic thin coat
19 bonding pad
32 LSI chip
35 bonding wire
30 printed board
31 interposer substrate
37 solder ball
33 printed wiring board
41 LSI-side pattern
43 LSI-side wire
45 bonding pad
47 via
51 printed-wiring-board-side pattern
53 printed-wiring-board-side wire
55 solder-ball pad
100 printed board
101 printed wiring board
102 power supply plane
103 ground plane
104 EBG structure
105 high-impedance surface
106 via
107 LSI package

1. A wiring substrate to be interposed when an electronic component including an integrated circuit is mounted on a printed wiring board, the wiring substrate comprising:
a signal wire transmitting a signal from the electronic component;
a power supply wire supplying a power voltage to the electronic component; and
a magnetic thin coat directly coating the power supply wire;
wherein the magnetic thin coat is arranged to be separated from the signal wire.

2. The wiring substrate according to claim 1, wherein closest portions between the signal wire and the magnetic thin coat are separated from each other by a specific distance or more.

3. The wiring substrate according to claim 1, wherein the magnetic thin coat is formed along the signal wire so as to be separated from the signal wire by a fixed distance.

4. The wiring substrate according to claim 1, wherein the signal wire and the magnetic thin coat are separated from each other by at least a half of a width of the signal wire.

5. The wiring substrate according to claim 1, wherein the magnetic thin coat is made of a material including ferrite.

6. The wiring substrate according to claim 1, wherein the magnetic thin coat is a resin magnetic composite coat in which magnetic particles are dispersed in resin.

7. A semiconductor device in which the electronic component has been mounted on the wiring substrate according to claim 1.

8. A printed board in which the electronic component has been mounted on the printed wiring board with the wiring substrate according to claim 1 interposed therebetween.

9. A method for producing a wiring substrate to be interposed when an electronic component including an integrated circuit is mounted on a printed wiring board, the method comprising:
forming a signal wire transmitting a signal from the electronic component, and a power supply wire supplying a power voltage to the electronic component; and
directly coating the power supply wire with a magnetic thin coat such that the magnetic thin coat is separated from the signal wire.

10. The method for producing a wiring substrate according to claim 9, the method comprising, at the time of forming the magnetic thin coat, directly coating the power supply wire with the magnetic thin coat such that a distance between the magnetic thin coat and the signal wire is kept constant along the signal wire.
